(19) United States
(12) Patent Application Publication
(10) Pub. No.: US 2013/0328191 A1
(43) Pub. Date: Dec. 12, 2013

(54) CTE ADAPTION IN A SEMICONDUCTOR PACKAGE

(71) Applicants: Thorsten Meyer, Regensburg (DE); Gerald Ofner, Regensburg (DE); Stephan Stoecki, Schwandorf (DE)

(72) Inventors: Thorsten Meyer, Regensburg (DE); Gerald Ofner, Regensburg (DE); Stephan Stoecki, Schwandorf (DE)

(73) Assignee: Intel Mobile Communications GmbH, Neubiberg (DE)

(21) Appl. No.: 13/494,324

(22) Filed: Jun. 12, 2012

(51) Int. Cl. H01L 23/48; H01L 23/52

(52) U.S. Cl. 257/738; 257/762; 257/E23.141; 257/E23.023

(57) ABSTRACT

A device such as a wafer-level package (WLP) device is proposed in which a dielectric layer is disposed between a surface of a semiconductor device and a surface of a redistribution layer (RDL). The dielectric layer may have at least one interconnect extending through the dielectric layer. The dielectric layer may have a coefficient of thermal expansion (CTE) value in a direction perpendicular to the surface of the semiconductor device that is less than a threshold value, and a Young's modulus that is greater than another threshold value. The dielectric layer may have a CTE value in a direction parallel to the surface of the semiconductor device at a surface of the dielectric layer facing the RDL that is greater than another threshold value

### BACKGROUND

For wafer-level package (WLP) semiconductor devices, achieving board level reliability during temperature cycling and drop testing may be challenging. WLP technology offers many potential advantages such as low cost, small dimensions, and excellent electrical and thermal performance. However, the number of temperature cycles before board-mounted failure of a package occurs is often lower than desired. A root cause of this failure may often be the relatively high degree of mismatch between the coefficient of thermal expansion (CTE) of the semiconductor chip of the package and the CTE of the printed circuit board (PCB) on which the package is mounted. This mismatch typically causes stress in the solder balls positioned between the package and the PCB during temperature cycling and may potentially lead to solder fatigue and early electrical fails, especially for the increasingly large package sizes used in the mobile computing and communications industries.

### SUMMARY

Some features described herein relate generally to structures and processes that may increase the reliability of wafer-level packages (WLPs) and similar packaging technologies. In some aspects, the coefficient of thermal expansion (CTE) of a WLP device may be increased to a value closer to the CTE of a circuit board to which the WLP device is to be mounted by adapting (e.g., determining) a material and a thickness of a dielectric layer included in the WLP device. For example, the material and the thickness of the dielectric layer may be adapted such that the dielectric layer has a high Young's modulus. Moreover, the CTE of the dielectric layer in a particular direction may be approximate in value to the CTE of interconnects (such as vias) extending in that direction through the dielectric layer.

According to some aspects, a device may be manufactured or otherwise provided to include a semiconductor device, a dielectric layer, and an electrically conductive redistribution layer (RDL) (e.g., a fan-in redistribution layer or a fan-out redistribution layer). The semiconductor device may have one or more electrical contacts laterally distributed on a surface of the semiconductor device. The dielectric layer may be disposed between the surface of the semiconductor device and a surface of the RDL. The dielectric layer may have one or more electrically conductive interconnects, such as vias, extending at least partially in a depth-wise direction through the dielectric layer and electrically coupling the one or more electrical contacts of the semiconductor device with the RDL. In some instances, the thickness of the dielectric layer may be less than 100 micrometers (e.g., between 5 and 15 micrometers, between 50 and 70 micrometers), although such a small thickness is not required. For example, the dielectric layer may have a thickness equal to or greater than 100 micrometers.

In some arrangements, the device may further include one or more solder balls electrically coupled to the redistribution layer. In such arrangements, the redistribution layer may be disposed between the dielectric layer and the one or more solder balls. In some arrangements, the device may further be coupled to, or may even include, a circuit board, such as a printed circuit board (PCB). In either case, the PCB may have electrical contacts that are electrically and mechanically coupled to the one or more solder balls. In such arrangements, the one or more solder balls may be disposed between the redistribution layer and the circuit board.

The dielectric layer may have a coefficient of thermal expansion (CTE) value in a direction perpendicular to the surface of the semiconductor device, and a Young's modulus. In some instances, the CTE value of the dielectric layer may be less than a threshold value (e.g., 32 ppm per degree Celsius). In some instances, a difference between the CTE value of the dielectric layer and a CTE value of the one or more interconnects extending through the dielectric layer may be less than another threshold value (e.g., 15 ppm per degree Celsius). In some instances, the Young's modulus of the dielectric layer may be greater than yet another threshold value (e.g., 25 GPa).

The dielectric layer may have a CTE value in a direction parallel to the surface of the semiconductor device that increases as the thickness of the dielectric layer increases due to the influence of the CTE of other materials which may be included in the package. For example, the dielectric layer may have a first CTE value at a surface of the dielectric layer facing the surface of the semiconductor device that is less than, for example, 3 ppm per degree Celsius. The same dielectric layer may have a second CTE value at a surface of the dielectric layer facing the surface of the redistribution layer that is greater than, for example, 6 ppm per degree Celsius. Thus, a gradient of the CTE between 3 ppm and 6 ppm (for example), may be present in the dielectric layer between the two surfaces.

This summary is not intended to identify critical or essential features of the disclosures herein, but instead merely summarizes certain features and variations thereof. Other details and features will also be described in the sections that follow.

### BRIEF DESCRIPTION OF THE DRAWINGS

A more complete understanding of the present disclosure and the potential advantages of various aspects described herein may be acquired by referring to the following description in consideration of the accompanying drawings, in which like reference numbers indicate like features, and wherein:

FIG. 1 illustrates a cross-sectional view of an example wafer-level packaging system;

FIG. 2 illustrates an isometric view of various components of an example wafer-level packaging system;

FIG. 3 illustrates an example technique for adapting a material and a thickness of a dielectric layer; and

FIG. 4 illustrates an example process flow for adapting a material and a thickness of a dielectric layer.

It is noted that one or more of the drawings may not necessarily be drawn to scale.

### DETAILED DESCRIPTION

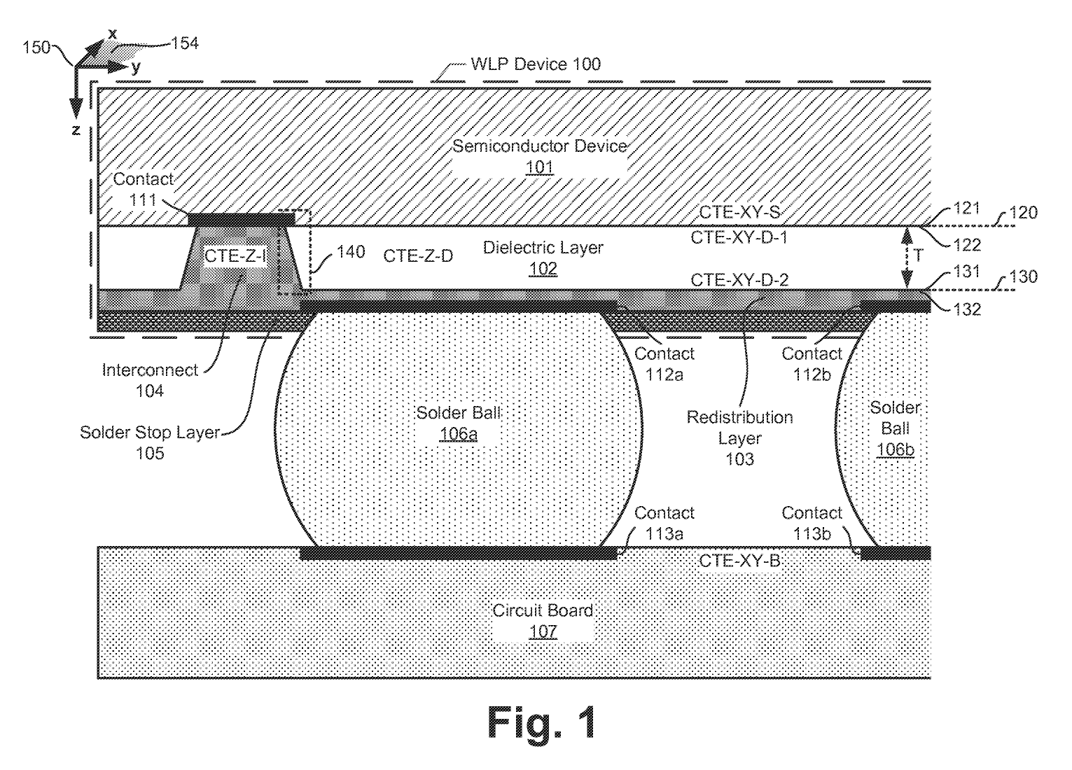

FIG. 1 illustrates a cross-sectional view of an example wafer-level packaging (WLP) system in accordance with one or more aspects described herein. The example WLP system may include, for example, WLP device 100 electrically coupled to circuit board 107 through one or more solder balls 106. In some aspects, the example WLP system may include more or less components, layers and/or features than those illustrated in FIG. 1. In some aspects, the physical arrangement of the components, layers and/or features of the example WLP system may differ from FIG. 1. Moreover, the WLP device 100 may include fewer or greater components. For example, the WLP device 100 may include the array of solder balls 106.

A coordinate system 150 is illustrated in FIG. 1 to represent relative positions, directions, and vectors that may be associated with various portions of the WLP device 100 and system, such as surfaces, interfaces between surfaces, regions proximate to surfaces, and the like. The coordinate system 150 is shown for explanation purposes only (and is not an actual physical element of the system), and may be Cartesian, polar, or any other suitable coordinate system even though the examples discussed herein refer to a Cartesian coordinate system. The coordinate system 150 in this example includes a z-axis extending upwards/downwards, a y-axis extending leftwards/rightwards perpendicular to the z-axis, and an x-axis extending “into the page” and “out of the page” perpendicular to both the y-axis and the z-axis. In some instances, surfaces described with reference to WLP device 100 may be described as being parallel to the x-y plane 154 indicated by coordinate system 150. However, the surfaces, the WLP device 100, and the system may be of any spatial orientation desired.

The WLP device 100 may include a semiconductor device 101, a dielectric layer 102, a redistribution layer (RDL) 103, one or more electrically conductive interconnects 104, a solder stop layer 105, one or more electrical contacts 111, and one or more electrical contacts 112. The semiconductor device 101 may comprise one or more active and/or passive components, such as electrical and/or optical components. For example, the semiconductor device 101 may be a chip or die that includes silicon-based materials (e.g., silicon, silicon carbide, silicon germanium, etc.), III-V compound semiconductor materials (e.g., gallium arsenide, gallium nitride, indium phosphide, indium antimonide, etc.), II-VI compound semiconductor materials (e.g., zinc oxide, zinc telluride, zinc selenide, etc.), and/or other semiconductor materials and combinations thereof. In one example, the semiconductor device 101 may include complementary metal-oxide-semiconductor (CMOS) components such as one or more resistors, transistors, capacitors, diodes, and/or memory cells, with one or more conductive lines interconnecting the same. In another example, the semiconductor device 101 may include microelectricalmechanical systems (MEMS) components such as transducers, sensors, and/or actuators, with one or more conductive lines interconnecting the same.

As illustrated in FIG. 1, the semiconductor device 101 may be included in a fan-in wafer-level ball grid array (WLB). In such a configuration, the one or more electrical contacts 111 may be made of an electrically conductive material and configured to allow the semiconductor device 101 to electrically communicate with other portions of the WLP device 100. The electrical contacts 111 may be, for example, metal contacts such as aluminum contact pads. The electrical contacts 111 may be disposed on or otherwise at a surface 121 of the semiconductor device 101 (e.g., a surface parallel to the x-y plane 154) facing downward (e.g., parallel to the z-axis). In some arrangements, the semiconductor device 101 may be included in a fan-out WLB. In such a configuration, the WLB surface (e.g., at interface 130) may include areas made of silicon and areas made of mold compound disposed adjacent to the areas of silicon. Accordingly, the CTEs at the bottom of the dielectric layer (e.g., at surface 122) may vary depending on whether the dielectric material is disposed adjacent to silicon or mold compound. As a result, the CTEs at the top of the dielectric layer (e.g., at surface 131) may vary in accordance with the CTEs at the bottom of the dielectric layer. In some arrangements, the semiconductor device 101 may be oriented in a flip-chip configuration that includes, for example, solder bumps and underfill.

The dielectric layer 102 may be disposed between the surface 121 of the semiconductor device 101 and a surface 132 of a redistribution layer (RDL) 103. A surface 122 of the dielectric layer 102 may be disposed facing the surface 121 of the semiconductor device 101, forming an interface 120 between the dielectric layer 102 and the semiconductor device 101. A surface 131 of the dielectric layer 102 may be disposed facing the surface 132 of the RDL 103, forming an interface 130 between the dielectric layer 102 and the RDL 103. The distance between the surfaces 122 and 131 (e.g., in a direction parallel to the z-axis) may correspond to a thickness T of the dielectric layer 102. The surfaces 121 and 122 may be in direct contact with each other or there may be one or more intervening layers between the surfaces 121 and 122. Likewise, the surfaces 131 and 132 may be in direct contact with each other or there may be one or more intervening layers between the surfaces 131 and 132.

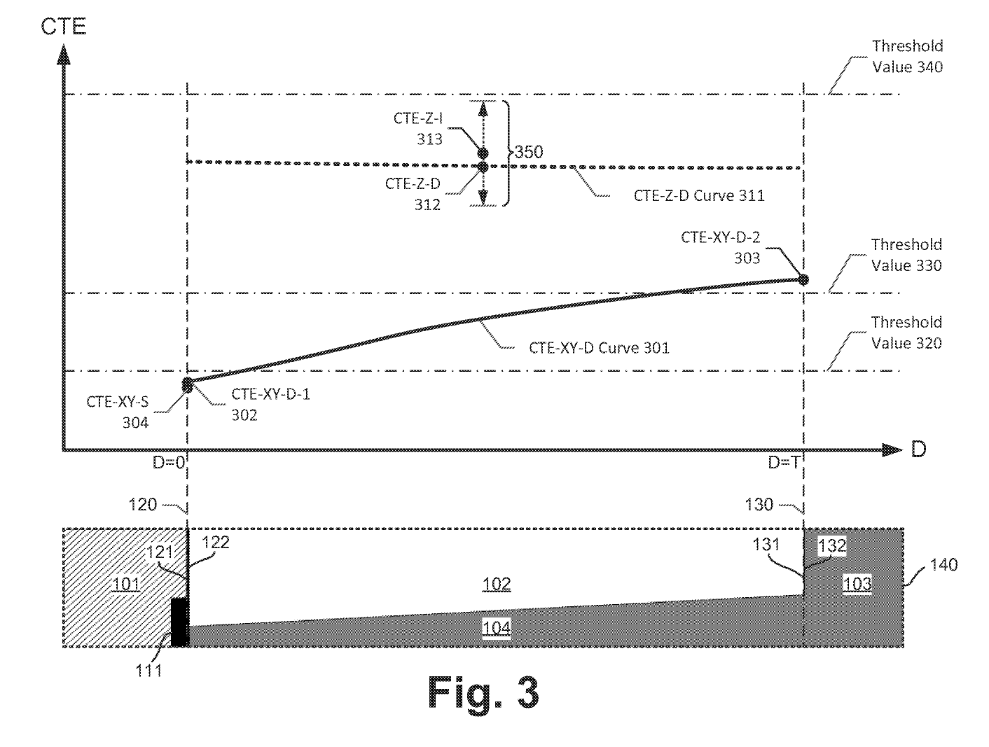

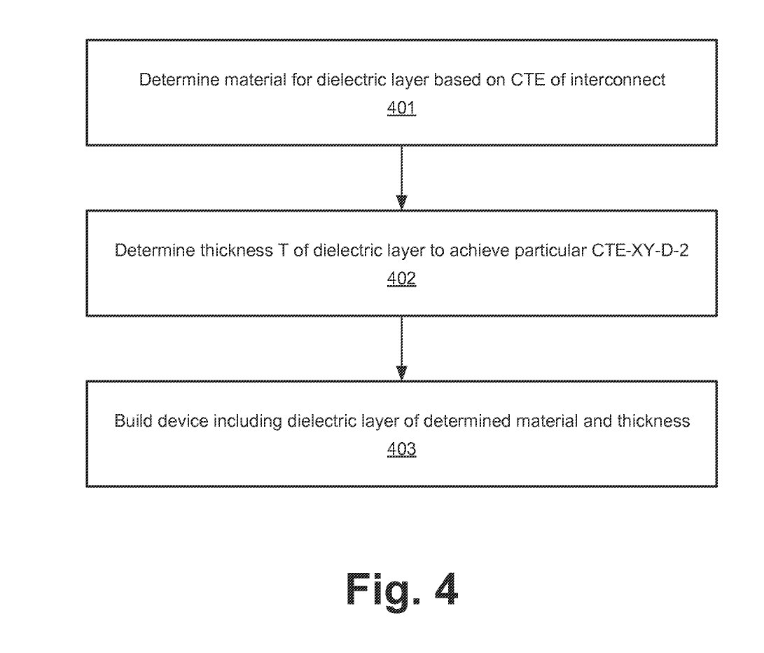

The dielectric layer 102 may comprise, for example, Epoxy and/or another dielectric material. In one example, the dielectric layer 102 may be made of a non-halogenated low coefficient of thermal expansion (CTE) bismaleimide-triazine (BT) resin such as HL832NX Type A. In another example, the dielectric layer 102 may be made of epoxy containing resin, for example, Epoxy-Phenolic or Cyanate Ester-Epoxy resin with or without filler. The dielectric layer 102 may be formed by, for example, spin-coating, developing, etching, and/or printing processes and/or lamination, curtain coating, spray coating and laser structuring. Techniques for determining the material and thickness of the dielectric layer 102 will be discussed in further detail below and with reference to FIGS. 3 and 4.

The dielectric layer 102 may include one or more electrically conductive interconnects, such as interconnect 104, extending through the dielectric layer 102 and electrically coupling the one or more electrical contacts 111 to the RDL 103. Interconnect 104 may be, for example, a via comprising an electrically conductive material such as copper, a metal stack, a metal-filled polymer (e.g., a silver-filled polymer), an isotropic conductive adhesive (ICA), or other electrically conductive material. The RDL 103 may be a fan-in or a fan-out redistribution layer comprising an electrically conductive material such as copper, a metal-filled polymer (e.g., a silver-filled polymer), an isotropic conductive adhesive (ICA), or other electrically conductive material. The dielectric layer 102 may be structured (e.g., by photolithography or by a laser) so as to expose the one or more electrical contacts 111 of the semiconductor device 101. Subsequently, the one or more interconnects 104, the RDL 103, or both may be formed by, for example, the use of sputtering, evaporation, plating resist, electroplating, stripping, etching, electro-less processes, dispensing, and/or printing processes. In one example, the one or more interconnects 104 may be one or more copper cylinders or posts that extend through the dielectric layer 102 and electrically couple the semiconductor device 101 to the RDL 103, which may include, e.g., patterned copper interconnects.

The RDL 103 may be disposed between the surface 131 of the dielectric layer 102 and the one or more solder balls 106. The one or more solder balls 106 may be made from tin, lead, indium, and/or any other solderable material or alloy. The RDL 103 may be electrically coupled to one or more solder balls 106 through one or more electrical contacts 112, which may each be in mechanical and electrical contact with one of the solder balls 106. The one or more electrical contacts 112 may have features similar to those discussed with reference to electrical contacts 111.

A solder stop layer 105 may be disposed adjacent to the RDL 103 and the solder balls 106. The solder stop layer 105 may be made of a non-solderable material (e.g., a solder resist such as WPR 5100, LTC 7320 or a laminated solder stop resin) and structured so as to expose the one or more electrical contacts 112 using, for example, photolithography or a laser.

The one or more solder balls 106 may be disposed between the RDL 103 and the circuit board 107. The circuit board 107 may be, for example, a printed circuit board (PCB). The solder balls 106 may be electrically and mechanically coupled to the circuit board 107 through one or more electrical contacts 113. The one or more electrical contacts 113 may have features similar to or different from those discussed with reference to the electrical contacts 111. In certain implementations, the one or more solder balls 106 may be arranged as a ball grid array (BGA) of solder balls disposed underneath the RDL 103 and electrically coupled (e.g., soldered) to the circuit board 107. Thus, the example WLP device 100 may be placed on the circuit board 107 as part of a larger circuit and/or device, such as a laptop, tablet, desktop, or server computer; a mobile phone; a global positioning system (GPS) device; an electronic medical device; an automobile or component thereof; an aircraft or component thereof; or any other device, system, or other product that includes electronics.

In some arrangements, each of the various layers and components of the example WLP system may have a respective coefficient of thermal expansion (CTE) and a respective Young's modulus (e.g., tensile modulus), and/or a range thereof. For anisotropic materials, the CTE may include an in-plane CTE component and an out-of-plane (e.g., cross-plane, through-plane) CTE component different from the in-plane CTE component. Referring to the example coordinate system of FIG. 1, an in-plane CTE component may correspond to a CTE value in a direction parallel to the x-y plane 154 and perpendicular to the z-axis (e.g., in a direction parallel to surface 121 of semiconductor device 101). An out-of-plane CTE may correspond to a CTE in a direction parallel to the z-axis and perpendicular to the x-y plane 154 (e.g., in a direction perpendicular to surface 121 of semiconductor device 101). For isotropic materials, the in-plane and out-of-plane CTE components may be equal or similar in value. For both isotropic and anisotropic layers of material, the CTE may vary at different locations within the layer. The actual CTE value at a given location within a layer may depend upon factors external to the layer, such as other materials mechanically coupled to and/or buried within the layer. Thus, a given layer may have a first in-plane or out-of-plane CTE at a first location within the layer, and a second different in-plane or out-of-plane CTE at a different second location within the layer. As will be discussed herein, such gradation of the CTE within the dielectric layer 102 may be used advantageously.

As illustrated in FIG. 1, the semiconductor device 101 may have an in-plane CTE value CTE-XY-S at or near the surface 121. The dielectric layer 102 may have an in-plane CTE value CTE-XY-D-1 at or near the surface 122 (e.g., facing the surface 121). The dielectric layer 102 may have an in-plane CTE value CTE-XY-D-2 at or near the surface 131 (e.g., facing the surface 132 of the RDL 103). The dielectric layer 102 may have an out-of-plane CTE value CTE-Z-D. The one or more interconnects (e.g., the interconnect 104) may have an out-of-plane CTE value CTE-Z-I. The circuit board 107 may have an in-plane CTE value CTE-XY-B at the surface that contacts the solder balls 106. The above-mentioned CTE values of FIG. 1 are those CTE values that are experienced in the environment of the complete system as shown in FIG. 1. It is noted that the CTE values for at least some of the layers, including the dielectric layer 102, may differ when those layers are in an isolated condition (e.g., not attached to any other layers). This difference is due at least in part to various forces and/or mechanical resistances may be experienced at the interfaces between the layers.

To provide a potentially more reliable device, the material of the dielectric layer 102 may be selected to have an in-plane CTE value (e.g., CTE-XY-D-2) similar to that of the circuit board 107 (e.g., CTE-XY-B) onto which the solder balls 106 are to be soldered. The material of the dielectric layer 102 may also be selected to have an out-of-plane CTE value (e.g., CTE-Z-D) similar to that of the one or more interconnects (e.g., the interconnect 104) (e.g., CTE-Z-I). In addition, the material of the dielectric layer 102 may be selected to have a Young's modulus high enough to allow for a thickness T of the dielectric layer 102 to be relatively small, such as less than 100 micrometers (e.g., to reduce the increasing potential for warpage caused by increasing the thickness T of the dielectric layer 102). In doing so, the stresses that may be experienced by the one or more solder balls 106 during a thermal event (e.g., environmental temperature variations such as increases or decreases in temperature) may be reduced and, in turn, the relative movement between the semiconductor device 101 and the circuit board 107 caused by these stresses may also be reduced. The stresses may be reduced because the in-plane CTE differential that would need to be absorbed by the solder balls 106 (the difference between the in-plane CTE at the RDL, which would be approximately CTE-XY-D-2 and the in-plane CTE-XY-B at the circuit board 107) may be decreased. Furthermore, the potential for delamination and/or cracking at the interface between the dielectric layer 102 and the interconnect 104 at or near surface 132 of the RDL 103 may be reduced in some instances as a result of any reduction in the mismatch between the out-of-plane CTEs of the dielectric layer 102 and the interconnect 104 (the difference between CTE-Z-D and CTE-Z-I). Techniques for determining the material and thickness of the dielectric layer 102 (e.g., using an expanded view of the region 140 of the WLP device 100 as a reference) are discussed by way of example in further detail with reference to FIG. 3.

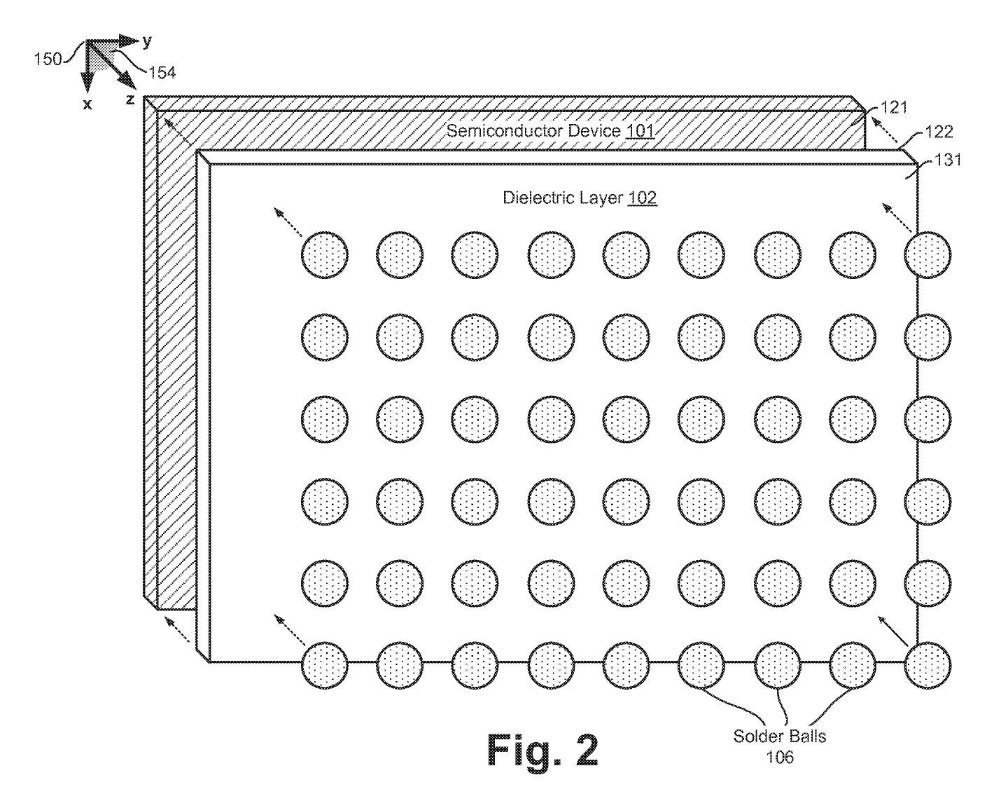

FIG. 2 illustrates an isometric exploded view of the semiconductor device 101, dielectric layer 102 and solder balls 106 in accordance with one or more aspects. Other layers and/or components of example WLP device 100 are not shown in FIG. 2 to avoid overcomplicating the drawing. As illustrated in FIG. 2, the coordinate system 150 is rotated such that the x-axis extends downwards, the y-axis extending rightwards perpendicular to the x-axis, and the z-axis extends perpendicular to both the x-axis and the y-axis. Surface 121 of semiconductor device 101 and surfaces 122 and 131 of dielectric layer 102 may each be parallel to the x-y plane 154.

FIG. 3 illustrates an example technique for adapting a material and a thickness of the dielectric layer 102. For purposes of illustration and not of limitation, the region 140 (see FIG. 1) of the WLP device 100 is used as a reference.

The dielectric layer 102 may be made of a material for which the in-plane CTE value of the dielectric layer 102 (when attached to the surrounding layers as in FIG. 1) increases as a function of the depth D extending downward from the surface 122 in the z-axis direction, as indicated by way of example in the CTE-XY-D curve 301 of FIG. 3. In some instances, the properties of curve 301, such as the linear or non-linear rate of increase of the in-plane CTE value CTE-XY-D with increases in depth D, may depend on the bulk (or out-of-plane) CTE value and the Young's modulus of the dielectric layer 102. For example, the semiconductor device 101 may have an in-plane CTE value CTE-XY-S 304 at or near the surface 121. The in-plane CTE value CTE-XY-S 304 may be, for example, approximately 3.0 ppm per degree Celsius for a silicon-based semiconductor device. Due to the high Young's modulus of silicon (e.g., above 100 GPa), the in-plane CTE value CTE-XY-D-1 302 at or near the surface 122 may be similar in value to the in-plane CTE value CTE-XY-S 304. For example, in-plane CTE value CTE-XY-D-1 302 may also be approximately 3.0 ppm per degree Celsius. In some arrangements, the in-plane CTE value CTE-XY-D-1 302 may be a value less than a predetermined threshold value 320 (e.g., 3 ppm per degree Celsius).

In some arrangements, the material and/or thickness T of dielectric layer 102 may be determined such that the in-plane CTE value CTE-XY-D-2 303 may have a value in between the in-plane CTE value CTE-XY-S 304 of the semiconductor device 101 and the in-plane CTE value CTE-XY-B of the circuit board 107 (e.g., approximately 16 ppm per degree Celsius for a PCB). For example, the material and thickness of dielectric layer 102 may be determined such that the in-plane CTE value CTE-XY-D-2 303 may have a value greater than a predetermined threshold value 330 (e.g., 6 ppm per degree Celsius). As a result, the dielectric layer 102 may absorb a portion of the stress caused by the mismatch of the CTE values CTE-XY-S and CTE-XY-B, thereby reducing the amount of stress absorbed by the one or more solder balls 106. However, delamination (e.g., between the semiconductor device 101 and the dielectric layer 102) or cracking (e.g., in the dielectric layer 102) may be more likely to occur if the in-plane CTE value CTE-XY-D-2 303 is too high or otherwise approaches the in-plane CTE value CTE-XY-B of the circuit board 107. Accordingly, the material and/or thickness T of dielectric layer 102 may be determined such that the in-plane CTE value CTE-XY-D-2 303 may have an intermediate value such as a value of approximately 7 to 10 ppm per degree Celsius. To reiterate, the above-mentioned CTE values are merely non-limiting examples.

The dielectric layer 102 may be made of a material having an out-of-plane CTE value CTE-Z-D 312 that remains relatively constant (e.g., within a particular range of a base or bulk value) with increasing depth D into the dielectric layer 102, as indicated by way of example by the CTE-Z-D curve 311. In some instances, the material of dielectric layer 102 may be determined such that the out-of-plane CTE value CTE-Z-D 312 may have a value less than a predetermined threshold value 340 (e.g., 32 ppm per degree Celsius) or in a particular predetermined range of values (e.g., between approximately 20 and 25 ppm per degree Celsius). In some instances, the material of dielectric layer 102 may be determined such that the out-of-plane CTE value CTE-Z-D 312 may be within a predetermined range 350 (e.g., ±15 ppm per degree Celsius) of the out-of-plane CTE value CTE-Z-D 313 of the interconnect 104 (e.g., approximately 10 ppm per degree Celsius for a copper interconnect). For example, the material of dielectric layer 102 may be determined such that the difference between CTE-Z-D 312 and CTE-Z-D 313 is less than a predetermined threshold value (e.g., 15 ppm per degree Celsius). In one example, the material of dielectric layer 102 may be determined such that the out-of-plane CTE value CTE-Z-D 312 may have a value of approximately 7 to 10 ppm per degree Celsius. In another example, the material of dielectric layer 102 may be determined such that the out-of-plane CTE value CTE-Z-D 312 may have a value of approximately 15 to 21 ppm per degree Celsius, which may allow for a reduction in the potential for cracking in the thickness range of the dielectric layer 102 (e.g., between approximately 50 and 70 micrometers).

The dielectric layer 102 may be made of a material having a Young's modulus high enough to support the desired CTE values CTE-XY-D-2 303 and CTE-Z-D 312. For example, the material of the dielectric layer 102 may be selected to have a Young's modulus greater than a predetermined threshold value (e.g., 25 GPa) or in a particular predetermined range of values (e.g., between approximately 24 and 34 GPa), which may allow for a thickness T of the dielectric layer 102 to be of a desirably small thickness, such as less than 100 micrometers and, in some instances, between 50 and 70 micrometers. Again, these and all other values mentioned herein are merely non-limiting examples.

In an illustrative example, the dielectric layer 102 may be made of a non-halogenated low CTE BT resin such as HL832NX Type A. For example, a HL832NX Type A dielectric layer 102 having a thickness T of 30 micrometers may have a CTE-XY-D-2 303 of 10.06 ppm per degree Celsius, a CTE-Z-D 312 of 30 ppm per degree Celsius, and a Young's modulus of 28 GPa. In another example, a HL832NX Type A dielectric layer 102 having a thickness T of 60 micrometers may have a CTE-XY-D-2 303 of 10.22 ppm per degree Celsius. In another example, a HL832NX Type A dielectric layer 102 having a thickness T of 100 micrometers may have a CTE-XY-D-2 303 of 10.47 ppm per degree Celsius. In another example, a HL832NX Type A dielectric layer 102 having a thickness T of 150 micrometers may have a CTE-XY-D-2 303 of 10.80 ppm per degree Celsius.

FIG. 4 illustrates an example process flow for determining a material and/or a thickness of a dielectric layer (e.g., dielectric layer 102) and building a device (e.g., WLP device 100) that includes the determined dielectric layer of the determined material and/or thickness. Some aspects of the example process flow may include aspects described with reference to FIGS. 1-3. Also, while the steps discussed with regard to FIG. 4 will reference the system of FIG. 1, this is only an example; these or similar steps may also be performed on variations of that system.

At step 401, a material for the dielectric layer (such as the dielectric layer 102) may be determined based at least on a desired or otherwise known CTE value of an interconnect (e.g., CTE value CTE-Z-I of interconnect 104) to be electrically coupled to the dielectric layer. For example, the material for the dielectric layer may be determined such that the out-of-plane CTE value (e.g., CTE-Z-D) of the dielectric layer is less than a threshold value (e.g., 32 ppm per degree Celsius, threshold value 340). In another example, the material for the dielectric layer may be determined such that a difference between the out-of-plane CTE value of the dielectric layer and the CTE value of one or more interconnects (such as the interconnect 104) in the dielectric layer is less than a predetermined threshold value (e.g., 15 ppm per degree Celsius, or such that CTE-Z-D is within the predetermined range 350). In some embodiments, the material for the dielectric layer may be determined such that the Young's modulus of the dielectric layer is greater than a threshold value (e.g., 25 GPa).

At step 402, a thickness T of the dielectric layer may be determined so as to achieve a particular predetermined in-plane CTE value, so as to be within a predetermined range of desired in-plane CTE values, so as to be greater than (or greater than or equal to) a predetermined in-plane CTE value, or so as to be less than (or less than or equal to) a predetermined in-plane CTE value. For example, the thickness T of the dielectric layer may be determined such that the in-plane CTE value (e.g., CTE-XY-D-2) of the dielectric layer at a surface (e.g., surface 131) of the dielectric layer facing a surface of a redistribution layer (e.g., RDL 103) is greater than a predetermined threshold value (e.g., 6 ppm per degree Celsius, threshold value 330). In some examples, the in-plane CTE value (e.g., CTE-XY-D-1) of the dielectric layer at a surface (e.g., surface 122) facing a semiconductor device (e.g., semiconductor device 101) may be less than a predetermined threshold value (e.g., 3 ppm per degree Celsius, threshold value 320).

At step 403, a device is manufactured that includes the dielectric layer made of the material determined at step 401 and the thickness T determined at step 402. For example, the device may include a WLP device (e.g., WLP device 100). In another example, the device may include the WLP device and one or more solder balls (e.g., solder balls 106) electrically coupled to the WLP device (e.g., to RDL 103). In another example, the device may include the WLP device, the one or more solder balls, and a circuit board (e.g., circuit board 107) electrically coupled to the one or more solder balls.

Thus, various examples have been described in which a material and a thickness of a dielectric layer of a device may be determined to increase its in-plane coefficient of thermal expansion (CTE) while keeping the out-of-plane CTE of the dielectric layer relatively close to the out-of-plane CTE of the interconnects that extend through the dielectric layer. As a result, a significant portion of the stress caused by the CTE mismatch between the device (such as a wafer-level package device) that includes the dielectric layer and a circuit board soldered to the device may absorbed by the dielectric layer and, in turn, the stress absorbed by the solder balls may be lowered. This may reduce the potential for circuit disconnections and/or short-circuiting caused by delamination and cracking during thermal events. In some instances, this may lead to a longer life and improve reliability in board-level testing, such as TCoB (Temperature, Cycle on Board) testing, independent of the size of the semiconductor device (e.g., the semiconductor device 101), the larger device (e.g., the WLP device 100), or both. In some instances, this may also allow for increased semiconductor device and/or overall device size due to the reduced stress absorbed by the solder balls as compared with conventional techniques. In some arrangements, such as if the warpage of the device exceeds a particular amount or becomes unacceptably high using the single-sided approach described herein, a dielectric or other material may be applied to the back side of the WLP device (e.g., at a surface of the semiconductor device 101 opposite the surface 121) in an appropriate thickness to at least partially compensate for the excessive warpage.

While various embodiments have been illustrated and described, there are merely examples. The words used in this specification are words of description rather than limitation, and it is understood that various changes may be made without departing from the spirit and scope of the present disclosure.

1. A device, comprising:
a semiconductor device having at least one electrical contact on a first surface of the semiconductor device;
a conductive redistribution layer; and
a dielectric layer disposed between the first surface and a surface of the redistribution layer, the dielectric layer having at least one interconnect extending through the dielectric layer and electrically coupling the at least one electrical contact with the redistribution layer,
wherein the dielectric layer has a coefficient of thermal expansion (CTE) value in a direction perpendicular to the first surface, and a Young's modulus,
wherein the CTE value of the dielectric layer is less than a first threshold value, wherein the first threshold is 32 ppm per degree Celsius and
wherein the Young's modulus of the dielectric layer is greater than a second threshold value, wherein the second threshold is 25 GPa.

2. The device of claim 1, further comprising at least one solder ball electrically coupled to the redistribution layer, wherein the redistribution layer is disposed between the dielectric layer and the at least one solder ball.

3. The device of claim 2, further comprising a circuit board electrically coupled to the at least one solder ball, wherein the at least one solder ball is disposed between the redistribution layer and the circuit board.

4. The device of claim 1, wherein the redistribution layer is one of a fan-in redistribution layer and a fan-out redistribution layer.

5-6. (canceled)

7. The device of claim 1,
wherein the dielectric layer has a first CTE value at a surface facing the first surface in a direction parallel to the first surface, and a second CTE value at a surface facing the surface of the redistribution layer in a direction parallel to the first surface,
wherein the first CTE value of the dielectric layer is less than 4 ppm per degree Celsius, and
wherein the second CTE value of the dielectric layer is greater than 6 ppm per degree Celsius.

8. The device of claim 7, wherein a thickness of the dielectric layer is less than 100 micrometers.

9. A device, comprising:
a semiconductor device having at least one electrical contact on a first surface of the semiconductor device;
a conductive redistribution layer; and
a dielectric layer disposed between the first surface and a surface of the redistribution layer, the dielectric layer having at least one interconnect extending through the dielectric layer and electrically coupling the at least one electrical contact with the redistribution layer,
wherein the dielectric layer has a coefficient of thermal expansion (CTE) value in a direction perpendicular to the first surface, and a Young's modulus,
wherein a difference between the CTE value of the dielectric layer and a CTE value of the at least one interconnect is less than a first threshold value, wherein the first threshold is 15 ppm per degree Celsius, and
wherein the Young's modulus of the dielectric layer is greater than a second threshold value, wherein the second threshold is 25 GPa.

10. The device of claim 9, further comprising at least one solder ball electrically coupled to the redistribution layer, wherein the redistribution layer is disposed between the dielectric layer and the at least one solder ball.

11. The device of claim 10, further comprising a circuit board electrically coupled to the at least one solder ball, such that the solder ball is disposed between the redistribution layer and the circuit board.

12. The device of claim 10, wherein the redistribution layer is one of a fan-in redistribution layer and a fan-out redistribution layer.

13-14. (canceled)

15. The device of claim 9,
wherein the dielectric layer has a first CTE value at a surface facing the first surface in a direction parallel to the first surface, and a second CTE value at a surface facing the surface of the redistribution layer in a direction parallel to the first surface,
wherein the first CTE value of the dielectric layer is less than 4 ppm per degree Celsius, and
wherein the second CTE value of the dielectric layer is greater than 6 ppm per degree Celsius.

16. The device of claim 15, wherein a thickness of the dielectric layer is less than 100 micrometers.

17. A device, comprising:
a semiconductor device comprising silicon and having at least one electrical contact at a first surface of the semiconductor device;
a conductive redistribution layer; and
a dielectric layer comprising epoxy and disposed between the first surface and a surface of the redistribution layer, the dielectric layer having at least one copper interconnect extending through the dielectric layer that electrically couples the at least one electrical contact with the redistribution layer
wherein the dielectric layer has a coefficient of thermal expansion (CTE) value in a direction perpendicular to the first surface, and a Young's modulus,
wherein a difference between the CTE value of the dielectric layer and a CTE value of the at least one copper interconnect is less than 15 ppm per degree Celsius, and
wherein the Young's modulus of the dielectric layer is greater than 25 GPa.

18. (canceled)

19. The device of claim 18,
wherein the dielectric layer has a first CTE value at a surface facing the first surface in a direction parallel to the first surface, and a second in CTE value at a surface facing a surface of the redistribution layer in a direction parallel to the first surface,
wherein the first CTE value of the dielectric layer is less than 4 ppm per degree Celsius, and
wherein the second CTE value of the dielectric layer is greater than 6 ppm per degree Celsius.

20. The device of claim 17, wherein a thickness of the dielectric layer is between 50 and 70 micrometers.
